(19) United States
(12) Patent Application Publication
(10) Pub. No.: US 2011/0233516 A1
(43) Pub. Date: Sep. 29, 2011

(54) OPTICAL SEMICONDUCTOR DEVICE INCLUDING PROTRUSION STRUCTURE OF PARALLELOGRAM CELLS AND ITS MANUFACTURING METHOD

(75) Inventor: Takuya KAZAMA, Kawasaki (JP)

(73) Assignee: STANLEY ELECTRIC CO., LTD., Tokyo (JP)

(21) Appl. No.: 13/069,892

(22) Filed: Mar. 23, 2011

(30) Foreign Application Priority Data
Mar. 23, 2010 (JP) 2010-065975

(51) Int. Cl. H01L 33/06

(52) U.S. Cl. 257/13; 438/33; 257/E33.032; 257/E33.012

(57) ABSTRACT

In an optical semiconductor device including a support body, semiconductor layers made of (Al_{z}Ga_{1-z})₁₋ₓInₓP (0≦z≦1, 0≦x≦1) having a light emitting layer provided above the support body, a first ohmic electrode layer provided on the semiconductor layers on the side of the support body, and a second ohmic electrode layer provided on the semiconductor layers, one of the semiconductor layers on the side of the second ohmic electrode layer has a protrusion structure including a plurality of parallelogram cells whose protrusion edges are connected to form ridges in a mesh shape. The first and second ohmic electrode layers have first and second line-shaped portions, respectively, in parallel with each other and distant from each other viewed from a thickness direction of the semiconductor layers. A longer diagonal line of each of the parallelogram cells is perpendicular to the first and second line-shaped portions of the first and second ohmic electrode layers.

This application claims the priority benefit under 35 U.S.C. §119 to Japanese Patent Application No. JP2010-065975 filed on Mar. 23, 2010, which disclosure is hereby incorporated in its entirety by reference.

### BACKGROUND

1. Field

The presently disclosed subject matter relates to an optical semiconductor device such as a light emitting diode (LED) and its manufacturing method.

2. Description of the Related Art

In a first prior art optical semiconductor device, an AlGaInP light emitting layer lattice-matching with GaAs and a GaInP contact layer not lattice-matching with GaAs are sequentially and epitaxially grown on a semiconductor growing GaAs substrate. Then, a reflective mirror is deposited thereon by a chemical vapor deposition (CVD) process or a sputtering process, to obtain a semiconductor laminated body. Then, the semiconductor laminated body is bonded to a support body. Finally, the GaAs substrate for absorbing a visible light component of light emitted from the AlGaInP light emitting layer is wholly removed (see: JP2006-86208A and JP2008-98336A). Thus, since the visible light absorbing GaAs substrate is wholly removed, light radiated from the AlGaInP light emitting layer to the reflective mirror is totally reflected at the reflective mirror to reach a light extracting face opposing the reflective mirror, so that a part of the totally-reflected light is extracted therefrom to the exterior, which would improve the light extracting efficiency. This will be described in detail later.

In order to suppress the total internal reflection component and the Fresnel component to enhance the light extracting efficiency, in a second prior art optical semiconductor device, two-dimensional periodic recesses are formed on the light extracting face (see: FIG. 7(c) of JP2005-5679A), and in a third prior art optical semiconductor device, two-dimensional periodic conical protrusions are formed on the light extracting face (see: JP2008-84973A). This will also be described in detail later.

In the above-described first, second and third prior art optical semiconductor devices, however, there is a trade-off relationship between the light extracting efficiency and the uniform spread of currents, i.e., the saturated current in the current-luminance characteristics, and therefore, it is impossible to enhance the light extracting efficiency and the saturated current, simultaneously.

### SUMMARY

The presently disclosed subject matter seeks to solve one or more of the above-described problems.

According to the presently disclosed subject matter, in an optical semiconductor device including a support body, semiconductor layers made of (Al_{z}Ga_{1-z})₁₋ₓInₓP (0≦z≦1, 0≦x≦1) having a light emitting layer provided above the support body, a first ohmic electrode layer provided on the semiconductor layers on the side of the support body, and a second ohmic electrode layer provided on the semiconductor layers, one of the semiconductor layers on the side of the second ohmic electrode layer has a protrusion structure including a plurality of parallelogram cells whose protrusion edges are connected to form ridges in a mesh shape. The first and second ohmic electrode layers have first and second line-shaped portions, respectively, in parallel with each other and distant from each other viewed from a thickness direction of the semiconductor layers. A longer diagonal line of each of the parallelogram cells is perpendicular to the first and second line-shaped portions of the first and second ohmic electrode layers. Thus, the flat portion of the light extracting face is reduced to change the total internal reflection into light incident to the light extracting face at an incident angle smaller than the critical angle, and enhance the spread of currents in the semiconductor layers.

Also, in a method for manufacturing an optical semiconductor device according to the presently disclosed subject matter, an n-type semiconductor layer, an active semiconductor layer and a p-type semiconductor layer made of (Al_{z}Ga_{1-z})₁₋ₓInₓP (0≦z≦1, 0≦x≦1) are formed. In this case, the active semiconductor layer is sandwiched by the n-type semiconductor layer and the p-type semiconductor layer. A first ohmic electrode layer is formed on a principal surface of the p-type semiconductor layer. A plurality of circular recesses are formed in the n-type semiconductor layer. An anisotropic etching process is performed upon the n-type semiconductor layer to form a protrusion structure including a plurality of parallelogram cells whose protrusion edges are connected to form ridges in a mesh shape. A second ohmic electrode layer is formed on the n-type semiconductor layer. The first and second ohmic electrode layers have first and second line-shaped portions, respectively, in parallel with each other and distant from each other viewed from a thickness direction of the semiconductor layers. A longer diagonal line of each of the parallelogram cells is perpendicular to the first and second line-shaped portions of the first and second ohmic electrode layers.

According to the presently disclosed subject matter, the light extracting efficiency and the saturated current can be simultaneously enhanced.

### BRIEF DESCRIPTION OF THE DRAWINGS

The above and other advantages and features of the presently disclosed subject matter will be more apparent from the following description of certain embodiments, as compared with the prior art, taken in conjunction with the accompanying drawings, wherein:

FIG. 1 is a cross-sectional view illustrating a first prior art optical semiconductor device;

FIG. 2 is a plan view of the reflective electrode layer, the n-side electrode and the bonding pad of FIG. 1;

FIG. 3A is a perspective view illustrating a second prior art optical semiconductor device;

FIGS. 3B and 3C are plan and cross-sectional scanning electron microscope (SEM) pictures, respectively, of the optical semiconductor device of FIG. 3A;

FIG. 4A is a perspective view illustrating a third prior art optical semiconductor device;

FIGS. 4B and 4C are plan and cross-sectional SEM pictures, respectively, of the optical semiconductor device of FIG. 4A;

FIG. 5 is a graph showing the light extracting efficiency characteristics of the optical semiconductor devices of FIGS. 1, 3A and 4A;

FIG. 6 is a graph showing the saturated current of current-luminance characteristics of the optical semiconductor devices of FIGS. 1, 3A and 4A;

FIGS. 7 and 8 are cross-sectional views illustrating an embodiment of the optical semiconductor device according to the presently disclosed subject matter;

FIG. 9 is a plan view of the reflective electrode layer, the n-side electrode and the bonding pad of FIGS. 7 and 8;

FIG. 10 is a plan view of the protrusion structure of the n-type AlGaInP layer of FIGS. 7 and 8;

FIGS. 11A and 11B are cross-sectional views taken along the line A-A and the line B-B, respectively, of FIG. 10;

FIG. 12 is a diagram illustrating a crystal lattice of the n-type AlGaInP layer of FIGS. 7 and 8;

FIGS. 13A, 14A and 15A are plan views for explaining a method for manufacturing the protrusion structure of FIGS. 7 and 8;

FIGS. 13B, 14B and 15B are cross-sectional views taken along the line B-B of FIGS. 13A, 14A and 15A, respectively;

FIGS. 16A and 16B are plan and cross-sectional SEM pictures, respectively, of the protrusion structure of FIGS. 14A and 14B;

FIGS. 17A and 17B are plan and cross-sectional SEM pictures, respectively, of the protrusion structure of FIGS. 15A and 15B;

FIG. 18 is a graph showing the light extracting efficiency characteristics of the optical semiconductor device of FIGS. 7 and 8 as compared with those of the first, second and third prior art optical semiconductor devices;

FIG. 19 is a graph showing the saturated current of current-luminance characteristics of the optical semiconductor device of FIGS. 7 and 8 as compared with those of the first, second and third prior art optical semiconductor devices;

FIG. 20 is a graph for explaining a slope of the protrusion structure of the n-type AlGaInP layer of the optical semiconductor device of FIGS. 7 and 8; and

FIGS. 21A, 21B and 21C are plan views illustrating modifications of FIG. 9.

### DETAILED DESCRIPTION OF EXEMPLARY EMBODIMENTS

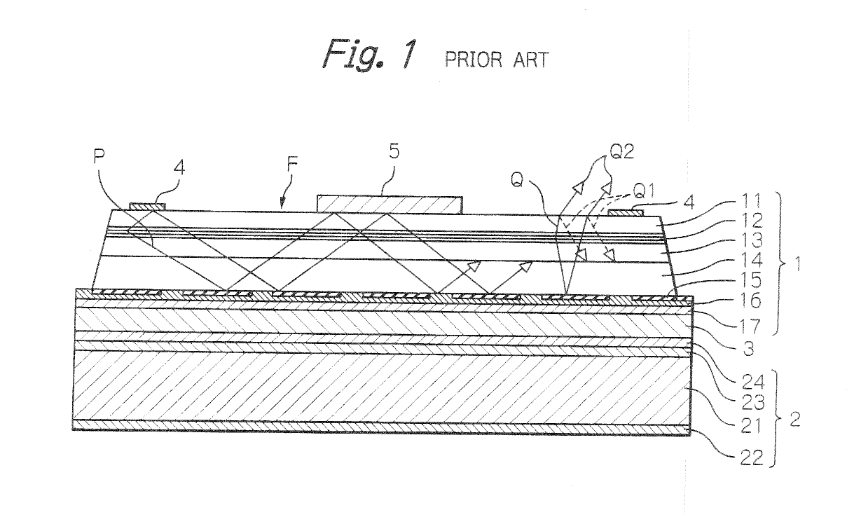

Before the description of exemplary embodiments, a prior art optical semiconductor device will now be explained with reference to FIGS. 1, 2, 3A, 3B, 3C, 4A, 4B, 4C, 5 and 6.

In FIG. 1, which illustrates a first prior art optical semiconductor device (see: JP2006-86208A and JP2008-98336A), this optical semiconductor device is constructed by a semiconductor laminated body 1, a support body 2, a bonding layer 3 for bonding the semiconductor laminated body 1 to the support body 2, an n-side electrode 4 and a bonding pad 5.

The semiconductor laminated body 1 includes semiconductor layers epitaxially-grown on a semiconductor growing GaAs substrate (not shown) using a metal organic chemical vapor deposition (MOCVD) process, i.e., an n-type AlGaInP layer 11, an AlGaInP active layer 12, a p-type AlGaInP layer 13 and a GaInP contact layer 14. In this case, the n-type AlGaInP layer 11, the AlGaInP active layer 12 and the p-type AlGaInP layer 13 form a double-heterostructured light emitting semiconductor layer. Also, the n-type AlGaInP layer 11, the AlGaInP active layer 12 and the p-type AlGaInP layer 13 lattice-match with GaAs, and are represented by (Al_{z}Ga_{1-z})₁₋ₓInₓP (0≦z≦1, 0≦x≦1). On the other hand, the GaInP contact layer 14 does not lattice-match with GaAs, and is represented by Ga₁₋ₓInₓP (0≦x≦1).

Additionally, the semiconductor laminated body 1 includes a patterned silicon oxide (SiO₂) layer 15 formed by a CVD process or the like beneath the GaInP contact layer 14 and an AuZn reflective electrode layer (p-side electrode) 16 formed by a sputtering process or the like beneath the silicon oxide layer 15. In this case, a combination of the silicon oxide layer 15 and the reflective electrode layer 16 serve as one reflective mirror. Also, the GaInP contact layer 14 is provided to have good ohmic contact characteristics with the p-side electrode 16. Further, the semiconductor laminated body 1 includes a barrier layer 17 for suppressing the outgoing diffusion of material of the reflective electrode layer 16 and the incoming diffusion of eutectic material at a post-stage process. The barrier layer 17 is made of refractory metal such as Ta, Ti or W, or their nitride formed by a sputtering process.

Thus, the semiconductor laminated body 1 includes the silicon oxide layer 15, the reflective electrode layer 16 and the barrier layer 17, in addition to the semiconductor layers 11 to 14.

The support body 2 includes a conductive support substrate 21 made of a boron-highly-doped monocrystalline silicon or the like, aback electrode layer 22 formed on a face of the conductive support substrate 21, an intermediate electrode layer 23 formed on the other face of the conductive support substrate 21 and an adhesive layer 24.

The bonding layer 3 is made of Au, SnNi or the like.

The n-side electrode 4 is made of AuGeNi or the like in ohmic contact characteristics with the n-type AlGaInP layer 11. Also, the bonding pad 5 is made of Au.

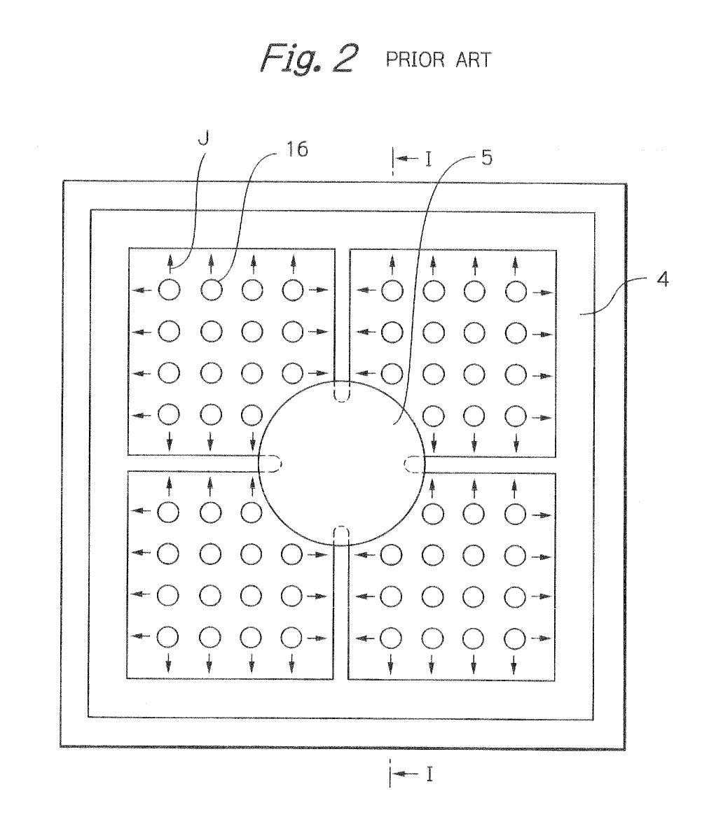

In FIG. 2, which is a plan view of the p-side electrode 16, the n-side electrode 4 and the bonding pad 5 of FIG. 1, the n-side electrode 4 is located at a periphery of the device to spread currents within the device, while the bonding pad 5 is located at a center of the device and connected to the n-side electrode 4 to supply currents from the center of the device to the n-side electrode 4.

Note that FIG. 1 is a cross-sectional view taken along the line I-I of FIG. 2.

The periphery of the semiconductor layers 11 to 14 of the semiconductor laminated body 1 is mesa-etched, and then, the device is diced so as to be separated into individual chips. Finally, as occasion demands, the entirety of the device is resin-molded (not shown).

In FIG. 1, the light extracting face (upper face) F of the semiconductor layers 11 to 14 is flat.

In FIG. 1, light P is emitted from the AlGaInP light emitting layer (11, 12, 13) and is directly or indirectly incident to the light extracting face F at an incident angle larger than the critical angle. This light P is multiply reflected between the light extracting face F and the reflective mirror, particularly, the silicon oxide layer 15 having a reflectivity of about 100%, so that the light P propagates transversely within the semiconductor layers 11 to 14 of the semiconductor laminated body 1. Finally, the light P is absorbed by the semiconductor layers 11 to 14 of the semiconductor laminated body 1, so that the light P cannot be extracted from the light extracting face F.

On the other hand, in FIG. 1, light Q is emitted from the AlGaInP light emitting layer (11, 12, 13) and is directly or indirectly incident to the light extracting face F at an incident angle smaller than the critical angle. A light component Q2 of the light Q except for its Fresnel component Q1 can be extracted from the light extracting face F.

For example, if the light extracting face F is molded by epoxy resin whose refractive index n is 1.5, the refractive index n of AlGaInP is 3.3, so that the critical angle is 27°. Therefore, the reflectivity of the light Q at the light extracting face F is about 15%, so that the light extracting efficiency is about 4.5%, which is still low.

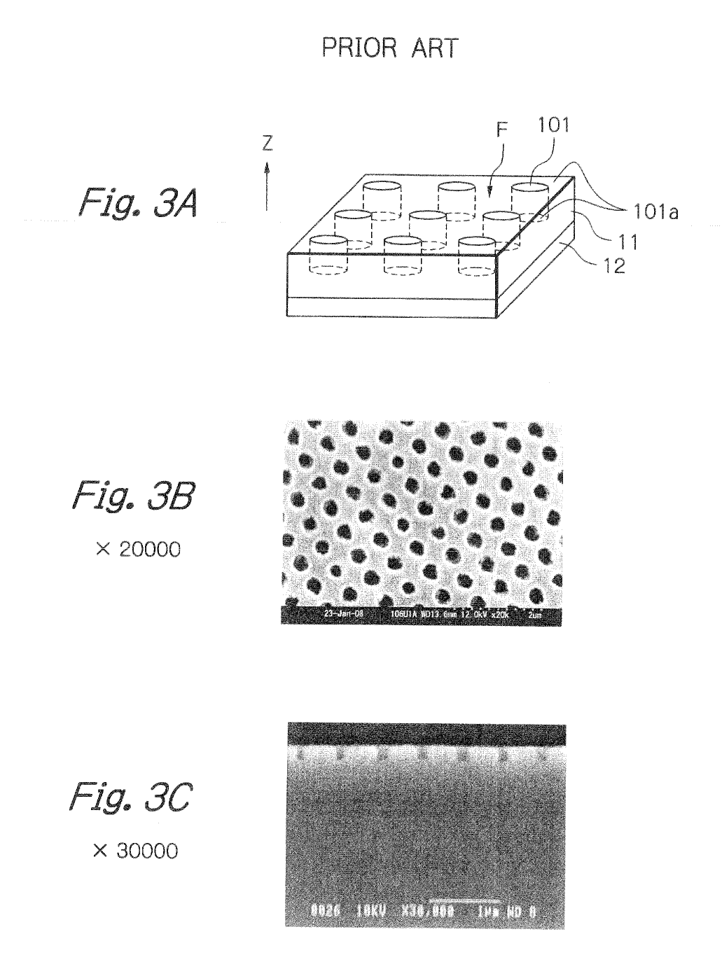

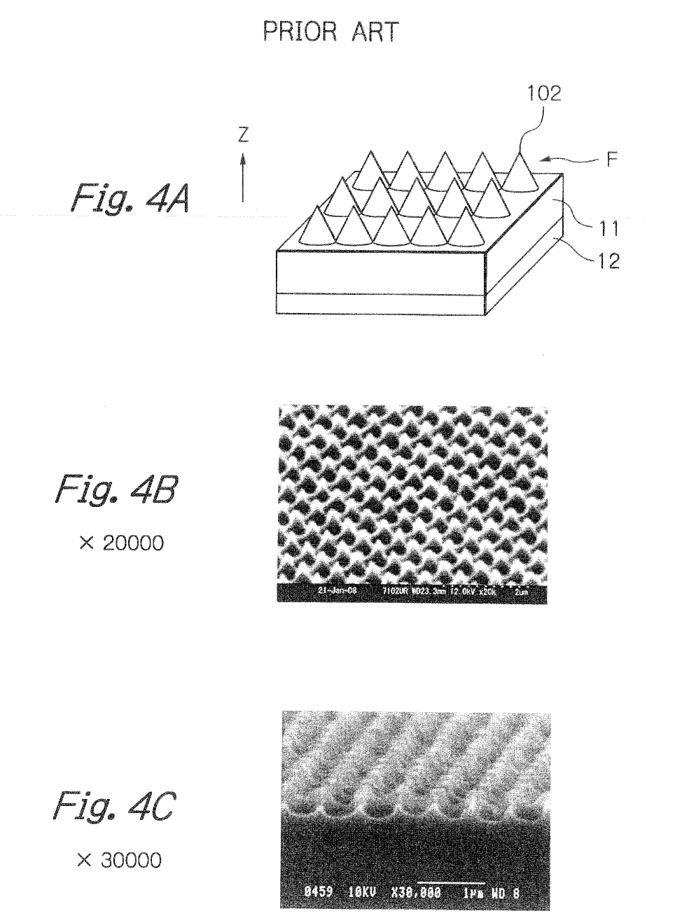

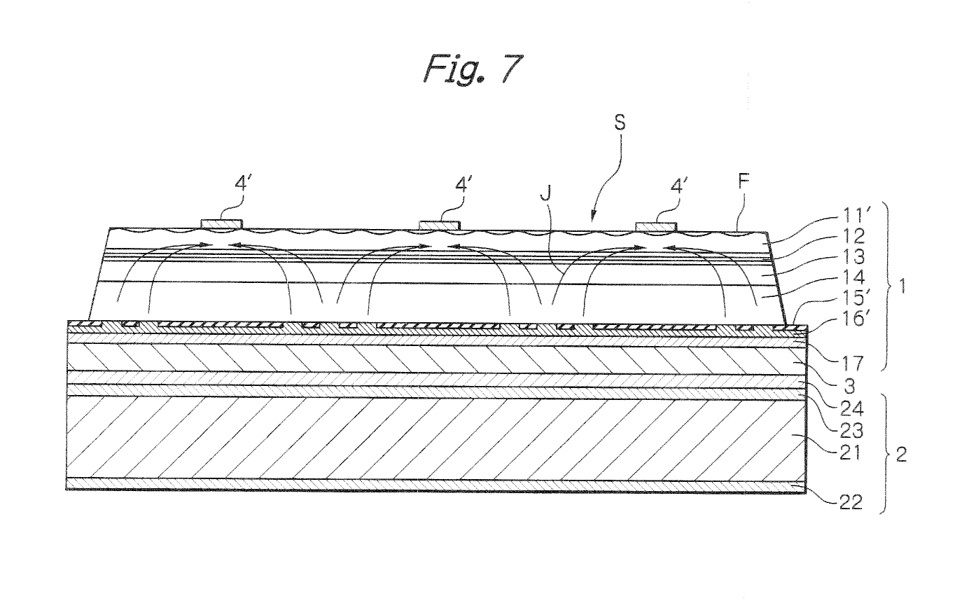

In order to suppress the total internal reflection component of the light P and the Fresnel component to enhance the light extracting efficiency, a second prior art optical semiconductor device is illustrated in FIG. 3A where two-dimensional periodic recesses 101 are formed on the light extracting face F (see: FIG. 7(c) of JP2005-5679A), and a third prior art optical semiconductor device is illustrated in FIG. 4A where two-dimensional periodic conical protrusions 102 are formed on the light extracting face F (see: JP2008-84973A). Note that FIGS. 3B and 3C are plan and cross-sectional scanning electron microscope (SEM) pictures, respectively, of the optical semiconductor device of FIG. 3A, and FIGS. 4B and 4C are plan and cross-sectional SEM pictures, respectively, of the optical semiconductor device of FIG. 4A. That is, in FIGS. 3A, 3B and 3C and FIGS. 4A, 4B and 4C, the light P is subjected by the two-dimensional periodic recesses 101 or the two-dimensional periodic conical protrusions 102 to scattering, diffraction and refraction, so that the light P is converted into light incident at an incident angle smaller than the critical angle, and thus, a large part of the light P may be extracted from the light extracting face F.

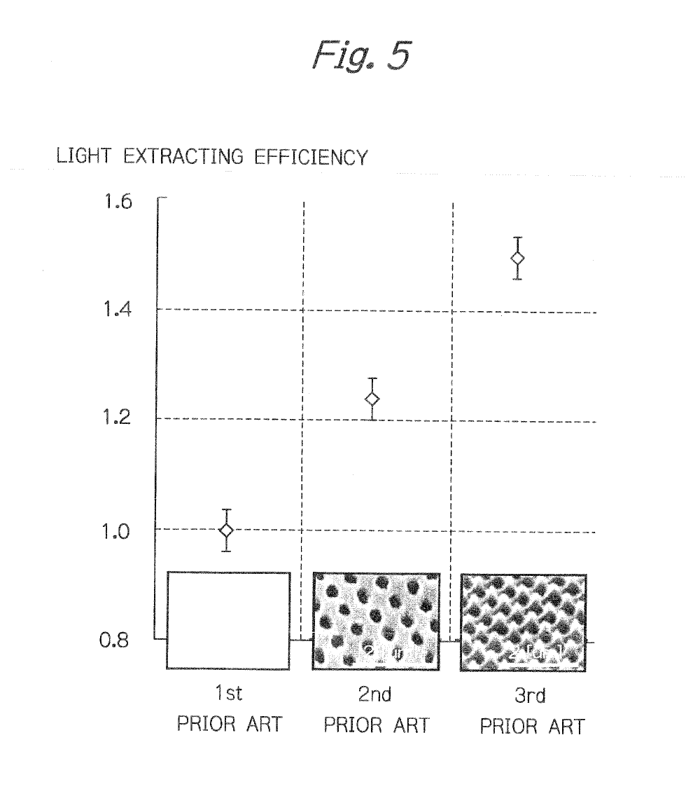

In FIG. 5, which shows the light extracting efficiency characteristics of the first, second and third prior art optical semiconductor devices of FIGS. 1, 3A and 4A, the light extracting efficiencies of the second and third prior art optical semiconductor devices of FIGS. 3A and 4A with two-dimensional-structured light extracting faces are higher than that of the first prior art optical semiconductor device of FIG. 1 with no two-dimensional-structured light extracting face. On the other hand, the light extracting efficiency of the second prior art optical semiconductor device of FIG. 3A with two-dimensional recesses on the light extracting face F is lower than that of the third prior art optical semiconductor device of FIG. 4A with two-dimensional conical protrusions on the light extracting face F, since the second prior art optical semiconductor device of FIG. 3A has flat portions 101a with total internal reflection characteristics.

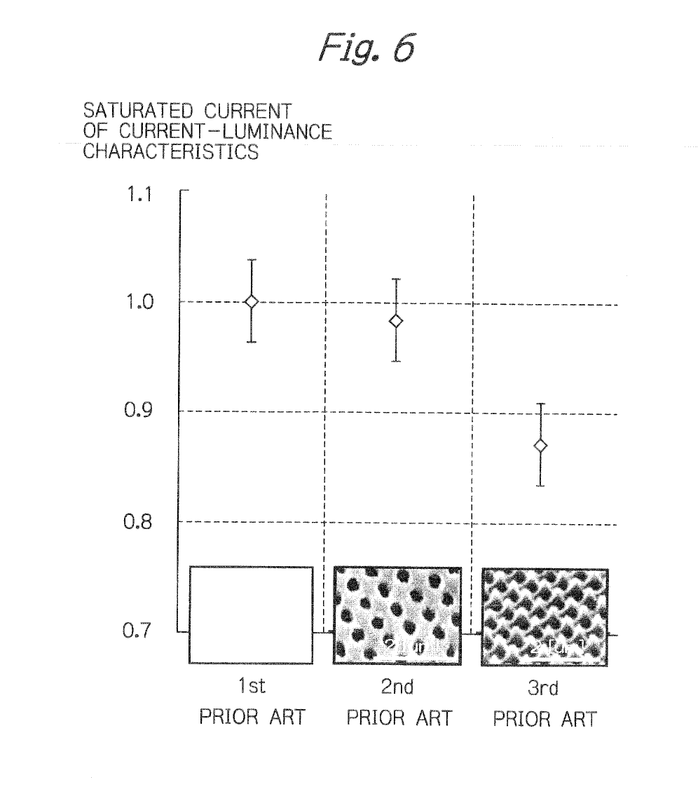

The light extracting face F of the semiconductor layer 11 would spread currents to uniformly supply the currents to the active layer 12 which can be represented by FIG. 6 which shows the saturated current of the current-luminance characteristics of the first, second and third prior art optical semiconductor devices of FIGS. 1, 3A and 4A. Note that the saturated current is defined by a current value at which the luminance is saturated in the current-luminance characteristics.

In the second prior art optical semiconductor device of FIG. 3A, the periphery of the two-dimensional periodic recesses 101 is so continuous that the thickness of the semiconductor layers is not substantially decreased. Therefore, the spread of currents is not so affected by the two-dimensional periodic recesses 101, to uniformly supply currents to the active layer 12. Thus, the saturated current of the second prior art optical semiconductor device of FIG. 3A is not so small as compared with those of the first prior art optical semiconductor device of FIG. 1.

On the other hand, in the third prior art optical semiconductor device of FIG. 4A, the two-dimensional periodic conical protrusions 102 are so separate that the thickness of the semiconductor layers is substantially decreased. Therefore, the spread of currents is so affected by the two-dimensional periodic conical protrusions 102, not to uniformly supply currents to the active layer 12. Thus, the saturated current of the third prior art optical semiconductor device of FIG. 4A is small compared with that of the second prior art optical semiconductor device of FIG. 3A.

In the prior art optical semiconductor devices of FIGS. 1, 3A and 4A, the luminous efficiency depends on the density of currents injected into the active layer 12. That is, when the spread of currents in the n-type AlGaInP layer 11 is insufficient to increase the density of currents injected into the active layer 12, carriers thereinto would overflow to decrease the saturated current in the current-luminance characteristics, i.e., to decrease the number of carriers contributing to the luminous efficiency.

Thus, in the prior art optical semiconductor devices of FIGS. 1, 3A and 4A, there is a trade-off relationship between the light extracting efficiency and the uniform spread of currents, i.e., the saturated current for the current-luminance characteristics, and therefore, it is impossible to enhance the light extracting efficiency and the saturated current, simultaneously.

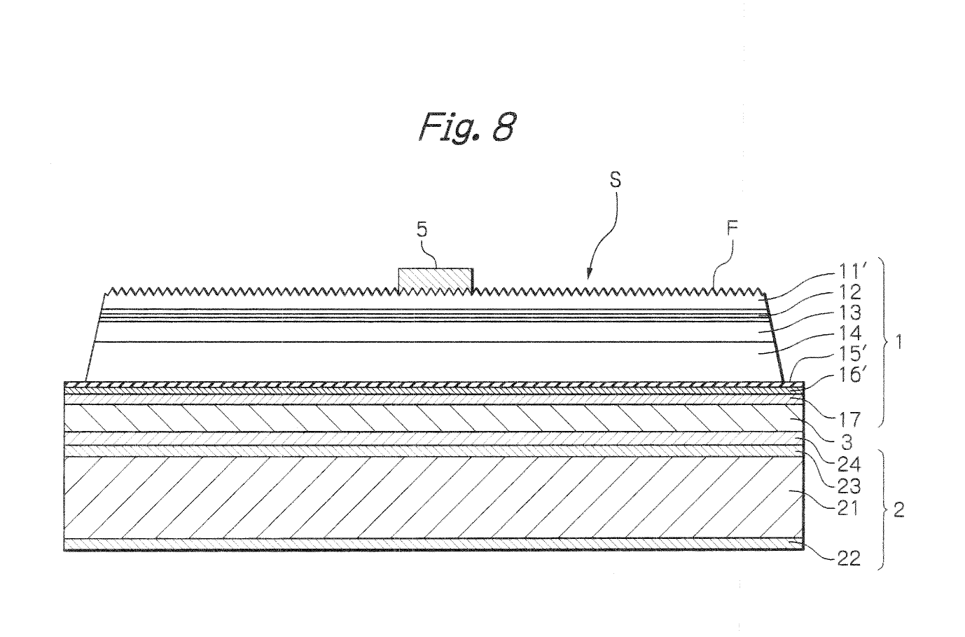

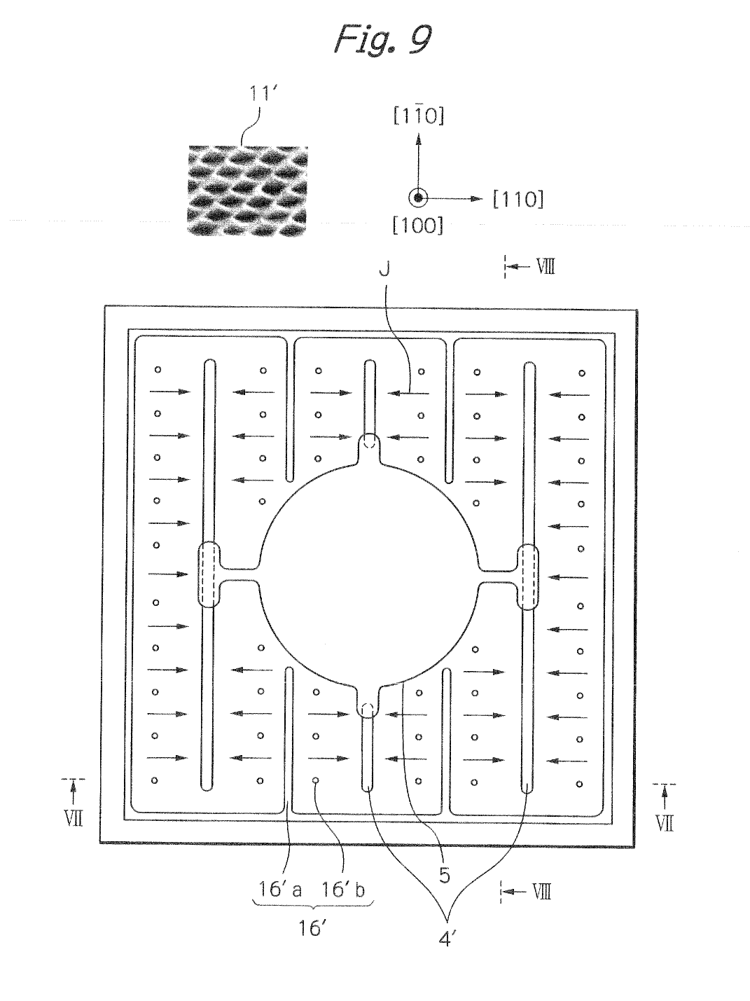

FIGS. 7 and 8 are cross-sectional views illustrating an embodiment of the optical semiconductor device according to the presently disclosed subject matter, and FIG. 9 is a plan view of the n-side electrode, the bonding pad and the AuZn reflective electrode layer of FIGS. 7 and 8. Note that FIGS. 7 and 8 are cross-sectional views taken along the line VII-VII and the line VIII-VIII, respectively, of FIG. 9. The optical semiconductor device of FIGS. 7, 8 and 9 has a chip size of about 300 μm×300 μm.

In FIGS. 7, 8 and 9, the n-type AlGaInP layer 11, the silicon oxide layer 15, the AuZn reflective electrode layer 16 and the n-side electrode 4 of FIG. 1 are replaced by an n-type AlGaInP layer 11′, a silicon oxide layer 15′, an AuZn reflective electrode layer 16′ and an n-side electrode 4′, respectively.

In FIGS. 7 and 8, the light extracting face F of the n-type AlGaInP layer 11′ forms a protrusion structure S to suppress the total internal reflection component and the Fresnel component, thus improving the light extracting efficiency.

In FIG. 9, the portion of the reflective electrode layer (p-side electrode) 16′ in ohmic contact with the GaInP contact layer 14 is formed by line-shaped portions 16′a and dot-shaped portions 16′b. The n-side electrode 4′ in ohmic contact with the n-type AlGaInP layer 11′ is formed by line-shaped portions in parallel with the line-shaped portions 16′a of the p-side electrode 16′. The line-shaped portions 16′a and the dot-shaped portions 16′b of the p-side electrode 16′ are not superposed on the line-shaped portions of the n-side electrode 4′ viewed from a thickness direction of the semiconductor layers 11′, 12, 13 and 14. In this case, the direction of the currents J is perpendicular to the line-shaped portions 16′a and the n-side electrode 4′.

In FIG. 9, the line-shaped portions 16′a and the n-side electrode 4′ are perpendicular to the face direction of the AlGaInP semiconductor layers.

Note that the line-shaped portions 16′a are about 5 μm in line width, for example, and the dot-shaped portions 16′b are about 5 μm in diameter, for example. The dot-shaped portions 16′b are arbitrarily arranged to uniformly spread the currents J. Particularly, if the semiconductor layers 11′, 12, 13 and 14 are thinner in total than about 6 μm, the dot-shaped portions 16′b avoid a partial current concentration to exhibit the current spreading effect. Further, the bonding pad 5 is about 100 μm in diameter.

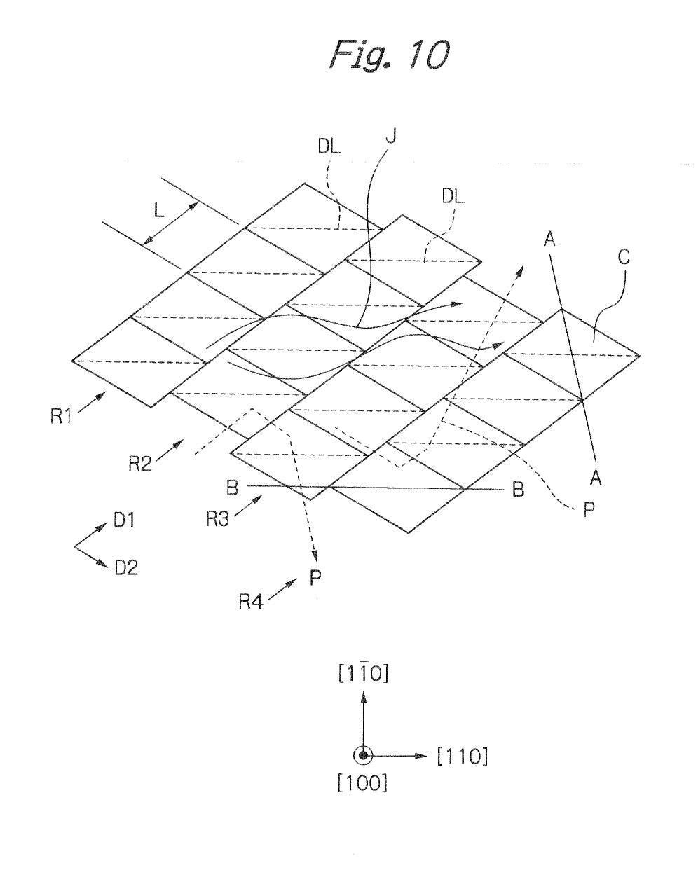

In FIG. 10, which is a plan view of the protrusion structure S of the n-type AlGaInP layer 11′ of FIGS. 7 and 8, the protrusion structure S of the n-type AlGaInP layer 11′ is constructed by a plurality of parallelogram cells C along the face direction [110] of the n-type AlGaInP layer 11′. Each of the parallelogram cells C has four protrusion edges forming one parallelogram. Ridges formed by the protrusion edges of the parallelogram cells C are connected to form a mesh shape.

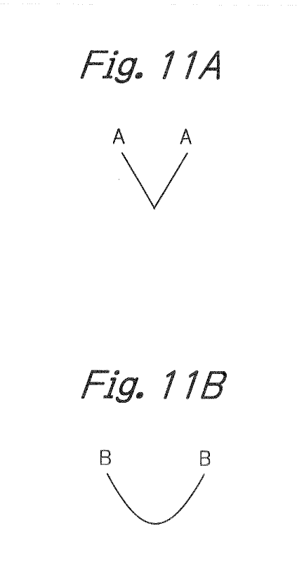

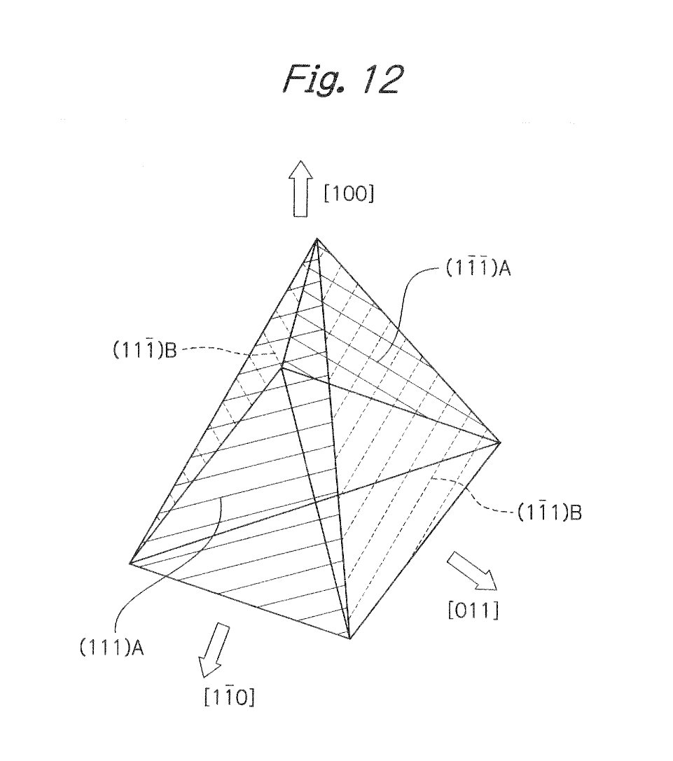

In FIGS. 11A and 11B, which are cross-sectional views of the protrusion structure S taken along the line A-A and the line B-B, respectively, of FIG. 10, the cross-section A-A is V-grooved, and the cross-section B-B is U-grooved. In this case, the V-grooved face of the n-type AlGaInP layer 11′ is mainly constructed by a (111)A face of the n-type AlGaInP layer 11′ (see: FIG. 12) which shows a crystal lattice of the n-type AlGaInP layer 11′.

A period L of the parallelogram cells C is represented by

λ/n≦L≦3.0μm

where λ is the wavelength of emitted light in free space of the semiconductor layers 11′, 12, 13 and 14, and

n is a refractive index of the n-type AlGaInP layer 11′ (n=3.3).

Here, if L<λ/n, no geometrical reflection effect is exhibited, so that the total internal reflection component cannot be effectively converted into light at an incident angle smaller than the critical angle. On the other hand, since the maximum thickness of the n-type AlGaInP layer 11′ manufactured by a MOCVD process is about 3 μm, the maximum value of the period L is about 3 μm. Preferably,

λ/n≦L≦1.2μm

For example, L=0.6 μm. Also, the V-grooved cross section A-A is about 0.6 μm in depth.

Each of the parallelogram cells C has two vertical angles different from 90°. Also, the parallelogram cells C have the same configuration, and each protrusion edge belongs to two adjacent parallelogram cells.

Each cell C is adjacent to six cells C. Also, a plurality of cell rows R1, R2, R3, R4, . . . , each formed by a plurality of cells along one direction D1, are shifted from each other, to suppress the propagation of light in the traverse direction, which would enhance the light extracting efficiency. In this case, the shift amount of the cell rows R1, R2, R3, R4, . . . can be determined in accordance with a desired current spread state and an optical output. In FIG. 10, note that the cell rows R1, R2, R3, R4, . . . are divided into two groups, and one group formed by the cells R1, R3, . . . is shifted from the other group formed by the cells R2, R4, . . . .

That is, peaks of one of the parallelogram cells C coincide with those of its adjacent ones arranged along the direction D1, while peaks of one of the parallelogram cells C do not coincide with those of its adjacent ones arranged along a direction D2. As a result, the parallelogram cells C form the cell rows R1, R2, R3, R4, . . . which are shifted from each other. Therefore, the protrusion edges of the parallelogram cells C are not arranged on straight lines, to suppress the propagation of light on the horizontal direction of the protrusion structure S. That is, due to the geometrical effect by the U-grooved cross section B-B, propagation light P incident to the light extracting face F at an incident angle larger than the critical angle is repeatedly reflected by the V-grooved cross section A-A and the U-grooved cross section B-B, so that a part of the propagation light P is converted into light incident to the light extracting face F at an incident angle smaller than the critical angle and is extracted from the light extracting face F, which would enhance the light extracting efficiency.

Also, as described above, in the protrusion structure S, the protrusion edges of the parallelogram cells C are connected to each other along the face direction [110]. Therefore, the currents J are unified and branched by each of the parallelogram cells C to spread the currents J. Thus, the currents J along the face direction [110] are not disturbed.

In FIGS. 9 and 10, a longer diagonal line DL of each of the parallelogram cells C is arranged along the face direction [110] of the n-type AlGaInP layer 11′ and is perpendicular to the line-shaped portions 16′a of the reflective electrode layer (p-side electrode) 16′ and the n-side electrode 4′. That is, the longer diagonal line DL of the parallelogram cells C of FIG. 10 is arranged along the direction of the currents J of FIG. 9. As a result, as illustrated in FIG. 10, the currents J can flow along the protrusion edges of the parallelogram cells C. Therefore, even if the protrusion structure S is formed on the n-type AlGaInP layer 11′, the spread of the currents J is hardly suppressed to uniformly inject the currents J into the active layer 12. Thus, the saturated current for the current-to-luminance characteristics is not so decreased as compared with the first prior art optical semiconductor device of FIG. 1 without the protrusion structure S.

In the above-described embodiment of the optical semiconductor device according to the presently disclosed subject matter, the light extracting efficiency and the saturated current can be enhanced simultaneously.

A method for manufacturing the optical semiconductor device of FIGS. 7, 8 and 9 will be explained below.

First, an about 3.0 μm thick n-type (Al_{0.7}Ga_{0.3})_{0.5}In_{0.5}P layer 11′, an about 0.5 μm thick AlGaInP active layer 12 and an about 1.0 μm thick p-type (Al_{0.7}Ga_{0.3})_{0.5}In_{0.5}P layer 13 are sequentially and epitaxially grown on a (100) face of an about 300 μm n-type GaAs substrate (not shown) having an OFF angle of 15° for growing semiconductors by an MOCVD process. The AlGaInP active layer 12 can be of a multiple quantum well (MQW) structure, of a single quantum well (SQW) structure or of a single layer. In this case, the n-type AlGaInP layer 11′, the AlGaInP active layer 12 and the p-type AlGaInP layer 13 lattice-match with the GaAs substrate. For example, the MQW structure is formed by 15 pairs each including an about 20 nm thick (Al_{0.1}Ga_{0.9})_{0.5}In_{0.5}P well layer and an about 10 nm thick (Al_{0.56}Ga_{0.44})_{0.5}In_{0.5}P barrier layer. Note that the aluminum composition z of (Al_{z}Ga_{1-z})_{0.5}In_{0.5}P active layer 12 is adjusted from 0 to 0.4 in accordance with the wavelength λ of emitted light, and the aluminum composition z of the n-type AlGaInP layer 11′ and the p-type (Al_{z}Ga_{1-z})_{0.5}In_{0.5}P layer 13 is adjusted from 0.4 to 1.0 in accordance with the wavelength λ of emitted light. In this case, the n-type AlGaInP layer 11′ and the p-type AlGaInP layer 13 can be formed by stacking a plurality of layers with different aluminum compositions Z. Then, an about 10 μm thick Ga₁₋ₓInₓP contact layer 14 where x is 0.1 is further grown by the MOCVD process. In this case, the composition x of Ga₁₋ₓInₓP is adjusted not to absorb light emitted from the light emitting semiconductor layer (11, 12, 13). Note that the GaInP contact layer 14 does not lattice-match with the GaAs substrate.

The OFF angle of the GaAs substrate is a slope angle of the (100) face of the GaAs substrate. When growing AlGaInP on the GaAs substrate, its OFF angle is generally from 0° to 15° in view of the ease of manufacturing and stability. However, the presently disclosed subject matter is not limited to the above-mentioned OFF angle, and the OFF angle can be from 0° to 20°.

Next, a silicon oxide layer (SiO₂) 15′ is formed on the Ga₁₋ₓInₓP contact layer 14 by an electron beam (EB) evaporating process, a sputtering process or a CVD process. The thickness t of the silicon oxide layer 15′ is represented by:

t=(λ/(4n))·m

where λ is the wavelength of emitted light in free space;

n is the refractive index of the silicon oxide layer 15′; and

m is a positive integer. If λ=625 nm, n=1.45 and m=3, then, t=320 nm.

Next, a photoresist pattern is formed by a photolithography process on the silicon oxide layer 15′. Then, the silicon oxide layer 15′ is etched by a wet etching process using buffered fluoric acid BHF using the photoresist pattern as an etching mask. The silicon oxide layer 15′ can be etched by a dry etching process. Then, an about 300 nm thick AuZn reflective electrode layer 16′ is formed by a resistance heating evaporating process, an EB evaporating process or a sputtering process. The partial etching of the silicon oxide layer 15′ results in that the Ga₁₋ₓInₓP contact layer 14 can be in ohmic contact with the reflective electrode layer 16′. The combination of the silicon oxide layer 15′ and the reflective electrode layer 16′ serve as one reflective mirror for reflecting light emitted from the active layer 12 to enhance the light extracting efficiency. Note that the silicon oxide layer 15′ can be replaced by another transparent dielectric material such as Si₃N₄ or Al₂O₃, and the reflective electrode layer 16′ can be replaced by another high reflectivity metal.

Note that if the above-mentioned reflective mirror is constructed by the reflective electrode layer 16′ only, an alloy layer is formed at an interface between the Ga₁₋ₓInₓP contact layer 14 and the reflective electrode layer 16′ by a nitrogen anneal alloy process which will be described later, so that the morphology deteriorates and the reflective electrode layer 16′ is diffused into the Ga₁₋ₓInₓP contact layer 14, and thus, the reflectivity is degraded.

Next, in order to protect the reflective electrode layer 16′ and obtain the adhesive characteristics of the reflective electrode layer 16′, a barrier layer 17 and an adhesive layer (not shown) are sequentially deposited on the reflective electrode layer 16′ by a resistance heating evaporating process, an EB evaporating process or a sputtering process.

The barrier layer 17 is made of refractory metal such as Ta, Ti or W, or its nitride. For example, TaN, TiW and TaN each having a thickness of about 100 nm is sequentially deposited. The barrier layer 17 suppresses the outgoing diffusion of material of the reflective electrode layer 16′ and the incoming diffusion of eutectic material of the adhesive layer. If the barrier layer 17 does not operate effectively, the electrical properties such as the increase of the forward voltage V_{f} would deteriorate and the reflectivity R of the reflective mirror (15′, 16′) would be decreased, to thereby decrease the luminance of the device.

Next, at a nitrogen annealing alloy step, an annealing process is carried out at a temperature of about 500° C. under nitrogen atmosphere. As a result, a good ohmic contact is realized between the GaInP contact layer 14 and the reflective electrode layer 16′ at the openings of the silicon oxide layer 15′.

Next, an adhesive layer (not shown) made of about 300 nm thick Ni and about 30 nm thick Au is formed on the semiconductor laminated body 1 by a resistance heating evaporating process, an EB evaporating process or a sputtering process. This adhesive layer improves the wettability with an eutectic bonding layer of the support body 2 to form a bonding layer 3 at a later thermal pressurizing step.

Next, a resistance heating evaporating process, an EB evaporating process or a sputtering process is carried out, so that a back electrode layer 22 is formed on a face of a conductive support substrate 21, and an intermediate electrode layer 23, an adhesive layer 24 made of AuSn, another adhesive layer (not shown) and a eutectic bonding layer (not shown) are sequentially formed on the other face of the conductive support substrate 21.

The conductive support substrate 21 is made of Si, Al, Cu, Ge or GaAs having good thermal conductivity. For example, the conductive support substrate 21 is made of p-type impurity highly-doped silicon.

Each of the back electrode layer 22 and the intermediate electrode layer 23 has good ohmic contact characteristics with the conductive support substrate 21. For example, each of the back electrode layer 22 and the intermediate electrode layer 23 is an about 100 to 300 nm (for example, 200 nm) thick Pt, Ni or Ti, which would improve the contact characteristics with the conductive support substrate 21 at a later thermal pressurizing step. As occasion demands, an alloy process is carried out under nitrogen atmosphere to realize better ohmic contact characteristics.

The adhesive layer 24 is made of about 100 to 300 nm (for example, 150 nm) thick Ti and about 50 to 150 nm (for example, 100 nm) thick Ni, to enhance the contact reliability between the intermediate electrode layer 23 and the adhesive layer of the semiconductor laminated body 1.

The adhesive layer of the support body 2 is made of about 50 to 150 nm (for example, 100 nm) thick Ni, NiV or Pt, to improve the wettability of the eutectic bonding layer of the bonding layer 3 at a later thermal pressing process. This eutectic bonding layer is made of about 300 to 3000 nm (for example, 600 nm) thick AuSn where Au:Sn=80 wt %:20 wt % (=70 at %:30 at %) made by a resistance heating evaporating process, an EB evaporating process or a sputtering process. In this case, suitable additives can be added to AuSn.

Next, the adhesive layer of the semiconductor laminated body 1 is bonded by a thermal pressurizing process to the adhesive layer and the eutectic bonding layer of the support body 2. As a result, the adhesive layers and the eutectic bonding layer are combined into a bonding layer 3 made of AuSnNi, for example, which is provided between the semiconductor laminated body 1 and the support body 2. In this case, the thermal pressurizing process is carried out at a bonding temperature of about 330° C. under a bonding pressure of about 1 MPa for about ten minutes. Note that the present invention is not limited to the above-mentioned thermal pressurizing conditions such as bonding materials, the bonding temperature, the bonding pressure and the bonding time, as long as the characteristics of the bonding layer 3 are not affected.

Next, the semiconductor growing GaAs substrate is removed by a wet etching process using an etchant of ammonia and hydrogen peroxide. Note that a dry etching process, a mechanical polishing process, a mechanical-chemical polishing (CMP) process or a combination of those processes may be used.

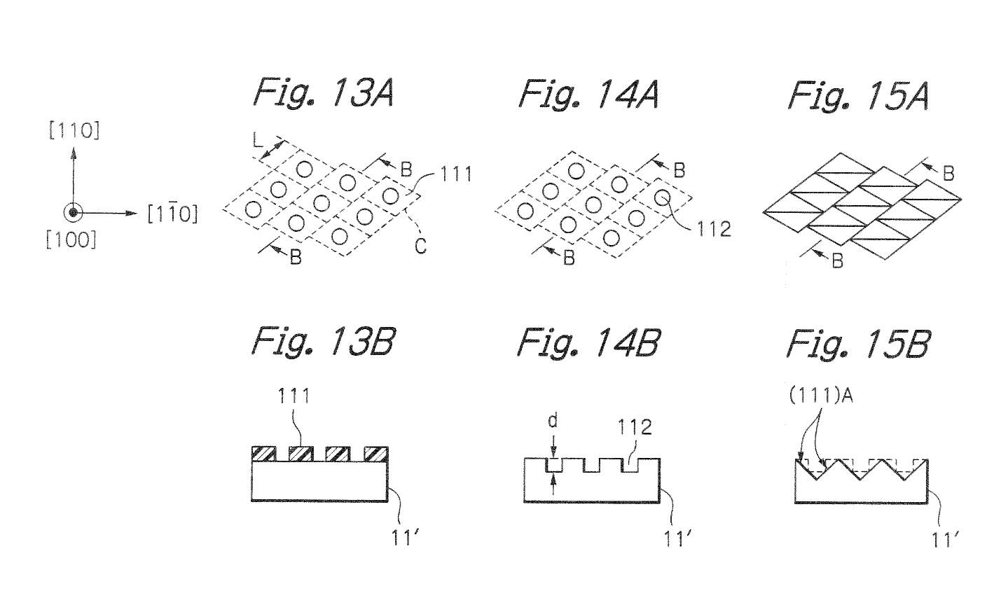

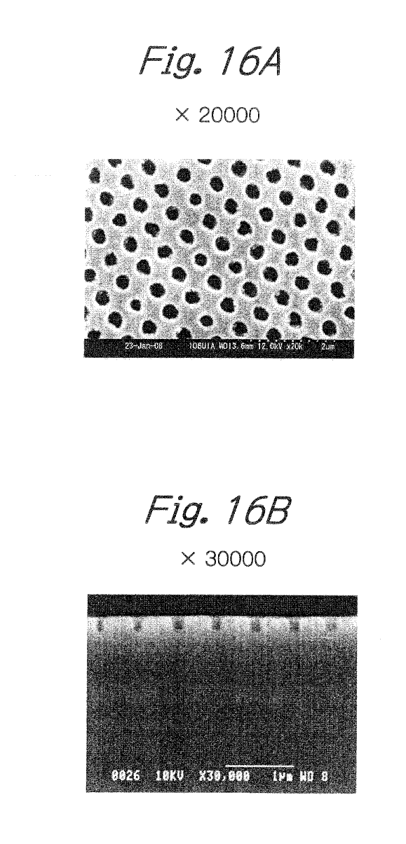

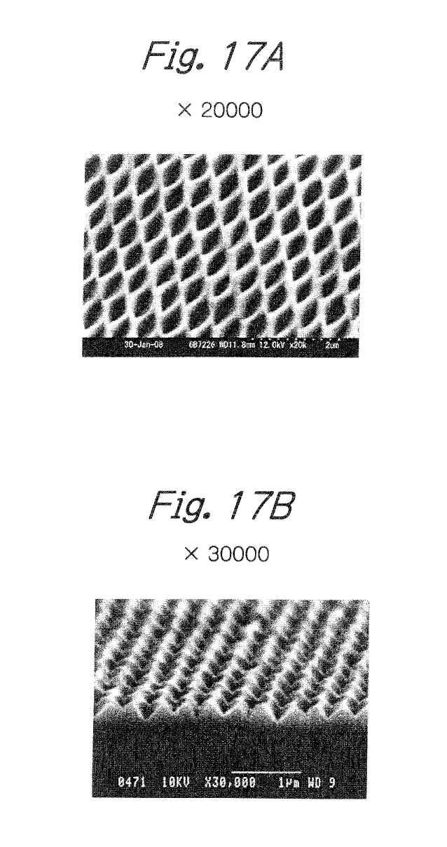

Next, a protrusion structure S is formed on the n-type AlGaInP layer 11′, which will be described with reference to FIGS. 12, 13A, 13B, 14A, 14B, 15A, 15B, 16A, 16B, 17A and 17B. Note that FIGS. 13A, 14A and 15A are plan views, and FIGS. 13B, 14B and 15B are cross-sectional views of FIGS. 13A, 14A and 15A, respectively. FIGS. 16A and 16B are SEM pictures of FIGS. 14A and 14B, respectively. FIGS. 17A and 17B are SEM pictures of FIGS. 15A and 15B, respectively.

First, the crystal lattice of the n-type AlGaInP layer 11′ is explained below with reference to FIG. 12. In FIG. 12, a (111)A face indicates that III-group elements Al, Ga and In appear on its uppermost face, a (111)B face indicates that a V-group element P appears on its uppermost face. In this case, if an anisotropic wet etching process using nitric acid (HNO₃) or nitric acid diluted by acetic acid (CH₃COOH) or pure water (H₂O), or using hydrochloric acid (HCl) or hydrochloric acid diluted by acetic acid (CH₃COOH) or pure water (H₂O) is used, the etching rate at the (111)B face is larger than the etching rate at the (111)A face. Therefore, when the (100) face, the (010) face and the (001) face are subjected to the above-mentioned wet etching process, the (111)B face rather than the (111)A face appears as illustrated in FIG. 12. In this case, note that the (111) face indicates a set of a (111) face, a (−111) face, a (1-11) face and a (11-1) face.

Next, referring to FIGS. 13A and 13B, a mask-patterned resist layer 111 for two-dimensional periodic circular recesses is formed by a photolithography process, an electron beam (EB) lithography process, an EB plotting process, a nano imprinting process or a laser exposure process. In this case, the period L of the cells C satisfies λ/n≦L≦3.0 μm as described above, and the maximum value of the period L is actually smaller than the maximum value 3.0 μm of the thickness of the n-type AlGaInP layer 11′ manufactured by a MOCVD process.

Next, referring to FIGS. 14A and 14B, a dry etching process using the resist layer 111 is carried out to form two-dimensional periodic circular recesses 112 in the n-type AlGaInP layer 11′, in order to form the (111)A face thereof. The two-dimensional periodic circular recesses 112 were actually observed by plan and cross-sectional SEM pictures as illustrated in FIGS. 16A and 16B. If L=0.6 μm, the depth d of the two-dimensional periodic circular recesses 112 is represented by d=(0.7˜1.5)·L. For example, d=0.6 μm. The arrangement of the two-dimensional periodic circular recesses 112 controls the arrangement of the parallelogram cells C and the cell rows R1, R2, R3, R4, . . . of FIG. 10.

Next, referring to FIGS. 15A and 15B, an anisotropic wet etching process using nitric acid (or diluted nitric acid) or hydrochloric acid (or diluted hydrochloric acid) is carried out so that the etching rate of the (111)B face>the etching rate of (111)A face. Even at an intermediate stage of the anisotropic wet etching process, the (111)A face whose etching rate is smaller is sloped. At a final stage of the anisotropic wet etching process, the two-dimensional periodic circular recesses 112 grow along the diagonal line of the parallelogram cells, i.e., along the direction [110] due to the larger etching rate of the (111)A face. On the other hand, the etching of the [11]-0] direction is hardly advanced due to the smaller etching rate of the (111)B face. The protrusion structure S were actually observed by plan and cross-sectional SEM pictures as illustrated in FIGS. 17A and 17B. In this case, each of the parallelogram cells is constructed by a bottom at the direction [110] and sloped faces subjected to the (111)A face on both sides of the bottom. Each of the parallelogram cells has an approximately V-shaped groove viewed along its shorter diagonal line. In the parallelogram cells, a pair of diagonal angles are not larger than 65°, and another pair of diagonal angles are not smaller than 115°.

Note that, when forming the protrusion structure S, a protection mask can be formed in an area where an n-side electrode 4′ and a bonding pad 5 will be formed later, as occasion demands.

Next, an n-side electrode 4′ made of AuGeNi having ohmic contact characteristics with AlGaInP is formed by a resistance heating evaporating process, an EB evaporating process or a sputtering process, and a lift-off process on the n-type AlGaInP layer 11′. In this case, AuGe, AuSn or AuSnNi can be used instead of AuGeNi. Then, a bonding pad 5 made of about 50 to 300 μm thick Ta, Ti or W, or its alloy or nitride for realizing a Schottky junction and about 1.5 μm thick Au is formed. Then, an annealing process at about 400° C. under nitrogen atmosphere is carried out on the n-side electrode 4′ and the bonding pad 5 for better ohmic contact characteristics.

Next, the semiconductor layers 11′, 12, 13 and 14 are mesa-etched to form grooves for separating the chips from each other.

Finally, the support body 2 of the device is diced by an etching process or a dicing laser scribing process, so that the device is separated into individual chips. As occasion demands, the entirety of the device is resin-molded (not shown).

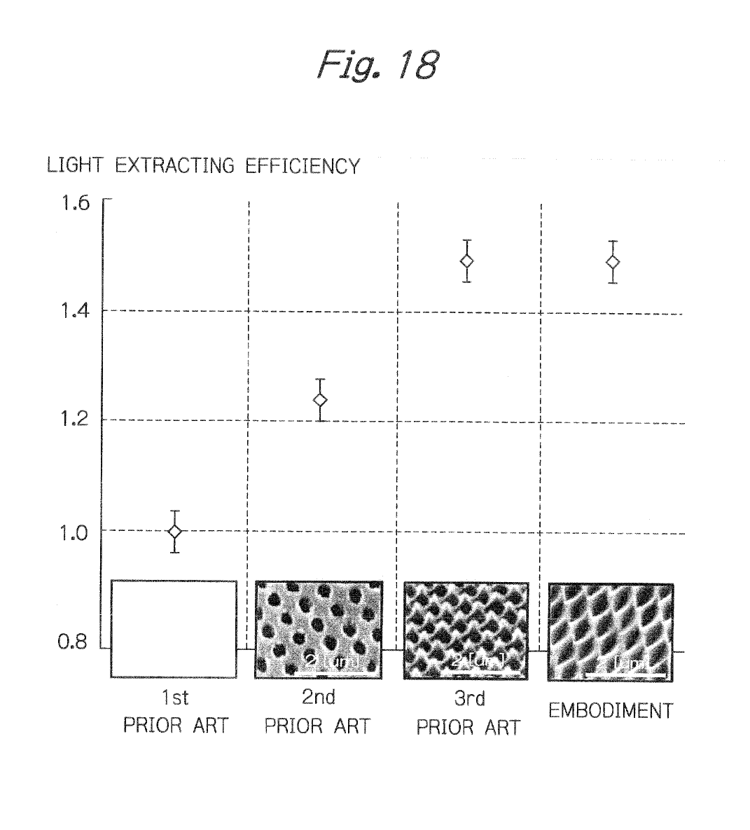

In FIG. 18, which shows the light extracting efficiency characteristics of the optical semiconductor device of FIGS. 7 and 8 as compared with those of the first, second and third prior art optical semiconductor devices of FIGS. 1, 3A and 4A, the light extracting efficiencies of the optical semiconductor device of FIGS. 7 and 8 with the protrusion structure S on the light extracting face F is high in the same way as in the third prior art optical semiconductor device of FIG. 4A with two-dimensional conical protrusions on the light extracting face F.

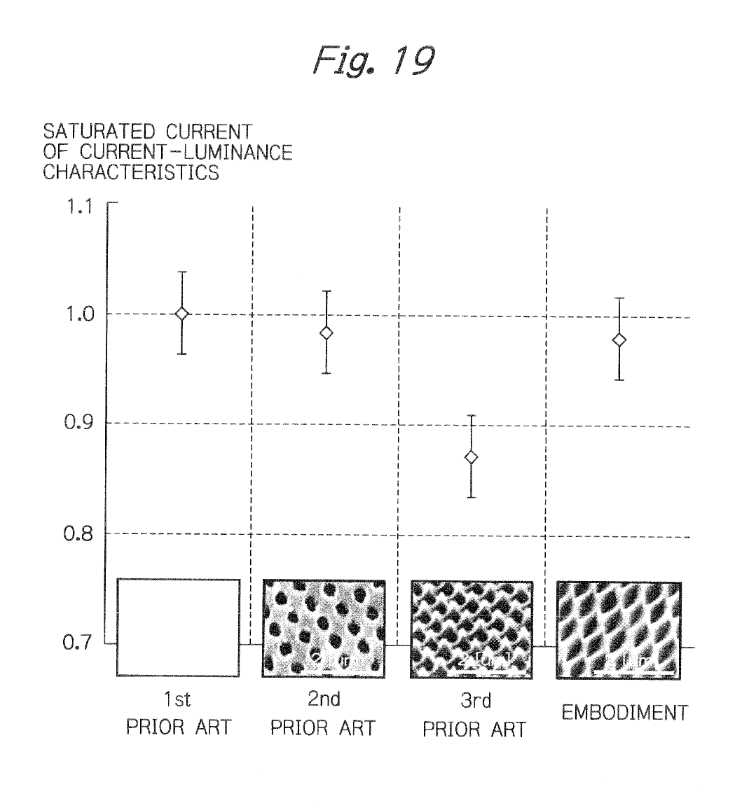

In FIG. 19, which shows the saturated current of the current-luminance characteristics of the optical semiconductor device of FIGS. 7 and 8 as compared with those of the first, second and third prior art optical semiconductor devices of FIGS. 1, 3A and 4A, since the optical semiconductor device of FIGS. 7 and 8 has the continuous protrusion structure S so that the ridges of the parallelogram cells C are continuous in a mesh state and the spread direction of the currents J is caused to be along the ridges of the parallelogram cells C, the spread of currents J is not so affected by the protrusion structure S, to uniformly supply currents to the active layer 12. Thus, the saturated current of the optical semiconductor devices of FIGS. 7 and 8 is not so small as compared with those of the first prior art optical semiconductor device of FIG. 1.

Thus, in the optical semiconductor devices of FIGS. 7 and 8, the light extracting efficiency can be enhanced, without greatly reducing the current spread characteristics, i.e., without greatly reducing the saturated current for the current-luminance characteristics.

As described above, since the longer diagonal line of each of the parallelogram cells C of the mesh-shaped protrusion structure S is arranged along the direction [110] of the AlGaInP layers 11′, 12 and 13, and also, the direction of the currents J supplied from the reflective electrode layer (p-side electrode) 16′ to the n-side electrode 4′ is arranged along the direction [110] of the AlGaInP layers 11′, 12 and 13, the saturated current for the current-luminance characteristics is hardly reduced. In this case, if an angle between the longer diagonal line of each of the parallelogram cells C of the mesh-shaped protrusion structure S and the direction of the currents J supplied from the reflective electrode layer (p-side electrode) 16′ to the n-side electrode 4′ is defined by θ, when 0≦θ≦15°, the saturated current for the current-luminance characteristics is hardly reduced. In this case, assume that the direction of the currents J is the direction of a line perpendicular to the line-shaped portions 16′a and the n-side electrode 4′ of FIG. 9.

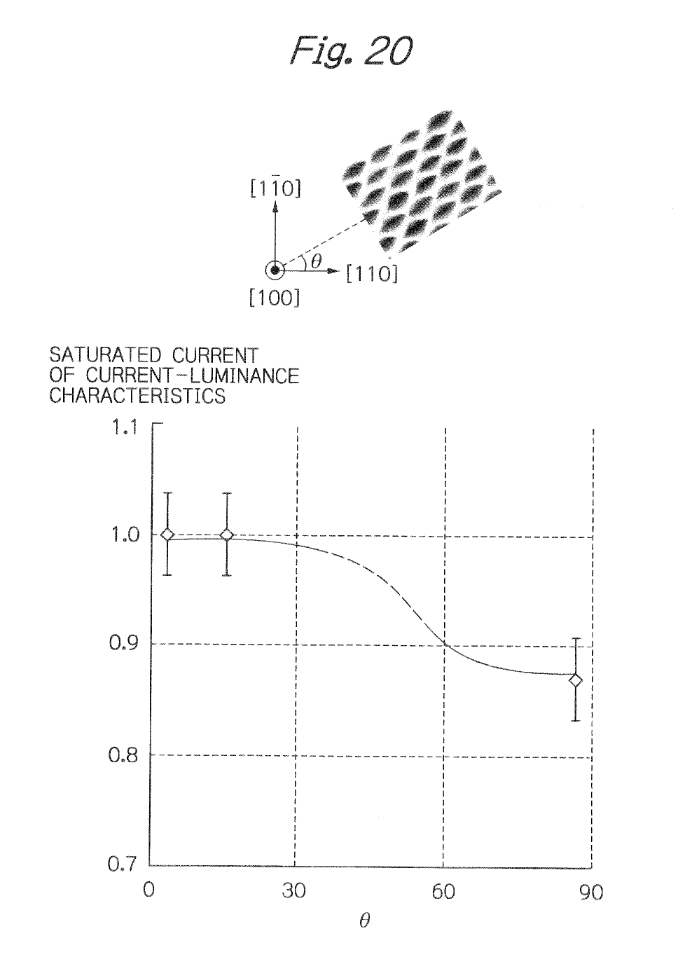

In more detail, FIG. 20 shows the normalized saturated current for the current-luminance characteristics of the optical semiconductor device of FIGS. 7 and 8 by only changing the above-mentioned angle θ. In this case, the inventor carried out experiments where θ=2°, 15° and 88°. Therefore, when θ=2°, the normalized saturated current was assumed at 1.0 at its center value. The normalized saturated current where θ=15° was the same as the normalized saturated current where θ=2°. On the other hand, the normalized saturated current where θ=88° was reduced as compared with the normalized saturated current where θ=2°. Therefore, when 0≦θ≦15°, an optical semiconductor device with a saturated current corresponding to that of the first prior art optical semiconductor device without any two-dimensional structure on the light extracting face F can be realized. Note that, when θ=88°, i.e., when the longer diagonal line of the parallelogram cells C was approximately in parallel with the line-shaped portions 16′a and the n-side electrode 4′, the saturated current was considerably reduced.

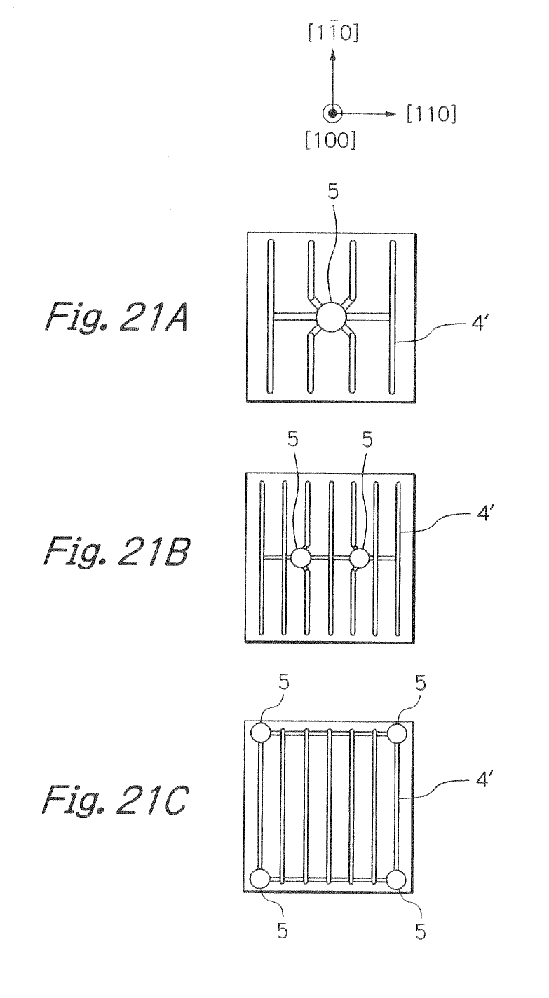

FIGS. 21A, 21B and 21C illustrate modifications of FIG. 9. That is, while the number of n-side electrodes 4′ is 3 in FIG. 9, the number of n-side electrodes 4′ can be other values such as 4 as illustrated in FIG. 21A. Also, while the number of bonding pads 5 is 1 in FIG. 9, the number of bonding pads 5 can be other values such as 2 and 4 as illustrated in FIGS. 21B and 21C. In any of FIGS. 21A, 21B and 21C, assume that the line-shaped portions 16′a of the reflective electrode layer (p-side electrode) 16′ are arranged in parallel with the n-side electrode 4′.

In the above-described embodiment, after the protrusion structure S is formed on the n-type AlGaInP layer 11′, the n-side electrode 4′ and the bonding pad 5 are formed thereon. However, after the n-side electrode 4′ and the bonding pad 5 are formed, the protrusion structure S can be formed on the n-type AlGaInP layer 11′. In this case, the n-side electrode 4′ and the bonding pad 5 are formed on the flat portion of the n-type AlGaInP layer 11′.

It will be apparent to those skilled in the art that various modifications and variations can be made in the presently disclosed subject matter without departing from the spirit or scope of the presently disclosed subject matter. Thus, it is intended that the presently disclosed subject matter covers modifications and variations of the presently disclosed subject matter provided they come within the scope of the appended claims and their equivalents. All related or prior art references described above and in the Background section of the present specification are hereby incorporated in their entirety by reference.

What is claimed is:

1. An optical semiconductor device comprising:
a support body;
semiconductor layers made of (Al_{z}Ga_{1-z})₁₋ₓInₓP (0≦z≦1, 0≦x≦1) including a light emitting layer provided above said support body;
a first ohmic electrode layer provided on said semiconductor layers on the side of said support body; and
a second ohmic electrode layer provided on said semiconductor layers,
one of said semiconductor layers on the side of said second ohmic electrode layer having a protrusion structure including a plurality of parallelogram cells whose protrusion edges are connected to form ridges in a mesh shape,
said first and second ohmic electrode layers having first and second line-shaped portions, respectively, in parallel with each other and distant from each other viewed from a thickness direction of said semiconductor layers,
a longer diagonal line of each of said parallelogram cells being perpendicular to said first and second line-shaped portions of said first and second ohmic electrode layers.

2. The optical semiconductor device as set forth in claim 1, wherein an angle between the longer diagonal line of each of said parallelogram cells and said first and second line-shaped portions is not larger than 15°.

3. The optical semiconductor device as set forth in claim 1, wherein a pair of diagonal angles of each of said parallelogram cells are not larger than 65°, and another pair of diagonal angles of each of said parallelogram cells are not smaller than 115°.

4. The optical semiconductor device as set forth in claim 1, wherein the longer diagonal line of each of said parallelogram cells is arranged along the face direction [110] of said semiconductor layers.

5. The optical semiconductor device as set forth in claim 1, wherein said parallelogram cells have a period L by
λ/n≦L≦3.0μm
where λ is a wavelength of emitted light in free space; and
n is a refractive index of said semiconductor layers.

6. The optical semiconductor device as set forth in claim 1, wherein said parallelogram cells are divided into a plurality of cell rows along one direction of said device, said cell rows being shifted from each other.

7. A method for manufacturing an optical semiconductor device comprising:
forming an n-type semiconductor layer, an active semiconductor layer and a p-type semiconductor layer made of (Al_{z}Ga_{1-z})₁₋ₓInₓP (0≦z≦1, 0≦x≦1), said active semiconductor layer being sandwiched by said n-type semiconductor layer and said p-type semiconductor layer;
forming a first ohmic electrode layer on a principal surface of said p-type semiconductor layer;
forming a plurality of circular recesses in said n-type semiconductor layer;
performing an anisotropic etching process upon said n-type semiconductor layer to form a protrusion structure including a plurality of parallelogram cells whose protrusion edges are connected to form ridges in a mesh shape; and
forming a second ohmic electrode layer on said n-type semiconductor layer,
said first and second ohmic electrode layers having first and second line-shaped portions, respectively, in parallel with each other and distant from each other viewed from a thickness direction of said semiconductor layers,
a longer diagonal line of each of said parallelogram cells being perpendicular to said first and second line-shaped portions of said first and second ohmic electrode layers.

8. The method as set forth in claim 7, wherein an angle between the longer diagonal line of each of said parallelogram cells and said first and second line-shaped portions is not larger than 15°.

9. The method as set forth in claim 7, wherein a pair of diagonal angles of each of said parallelogram cells are not larger than 65°, and another pair of diagonal angles of each of said parallelogram cells are not smaller than 115°.

10. The method as set forth in claim 7, wherein the longer diagonal line of each of said parallelogram cells are arranged along the face direction [110] of said n-type semiconductor layer, said active semiconductor layer and said p-type semiconductor layer.

11. The method as set forth in claim 7, wherein said parallelogram cells have a period L by
λ/n≦L≦3.0μm
where λ is a wavelength of emitted light in free space; and
n is a refractive index of said n-type semiconductor layer, said active semiconductor layer and said p-type semiconductor layer.

12. The method as set forth in claim 7, wherein said parallelogram cells are divided into a plurality of cell rows along one direction of said device, said cell rows being shifted from each other.
